(19) United States
(12) Patent Application Publication
(10) Pub. No.: US 2015/0195923 A1
(43) Pub. Date: Jul. 9, 2015

(54) Ergonomic Computer Design

(71) Applicant: PASSAM YUSEF YUSEF, Valencia (VE)

(72) Inventor: PASSAM YUSEF YUSEF, Valencia (VE)

(21) Appl. No.: 14/147,041

(22) Filed: Jan. 3, 2014

(51) Int. Cl. H05K 5/00; G06F 1/16; H05K 5/02

(52) U.S. Cl. CPC H05K 5/0017; H05K 5/0247; G06F 1/1601; H05K 5/0234

(57) ABSTRACT

The current invention is an ergonomically designed computer with a base with a computer cabinet which has a flat large screen with the cabinet connected to the base by a leg with USB and sound ports on its side for ease of access. The computer is ergonomically designed for ease of use and is streamed line for artistic viewing.

### CROSS-REFERENCES TO RELATED APPLICATIONS

None

### FIELD OF THE INVENTION

This device refers to the field of computers in more an ergonomic computer design.

### BACKGROUND OF THE INVENTION

Today's computers are blocky and not artistically appealing. They are designed with costs in mind and they are not ergonomically designed putting stress on the user when they use their computers. Many still have keyboards and mouses that are still wired to them. The desktops use more of the desktop than what is needed and can be very unappealing to look at.

There remains room for improvement in the art.

### SUMMARY OF THE INVENTION

The current invention is a ergonomically designed computer with a base with a computer cabinet which has a flat large screen with the cabinet connected to the base by a leg. The computer is ergonomically designed for ease of use and is streamed line for artistic viewing. The computer will have a USB and sound ports on its side for ease of access.

### BRIEF DESCRIPTION OF DRAWINGS

Without restricting the full scope of this invention, the preferred form of this invention is illustrated in the following drawings in which:

FIG. 1 displays the Ergonomic Computer;

FIG. 2 displays another view of the computer; and

FIG. 3 shows the wireless mouse and keyboard connecting to the computer.

### DETAILED DESCRIPTION OF THE PREFERRED EMBODIMENT

There are a number of significant design features and improvements incorporated within the invention.

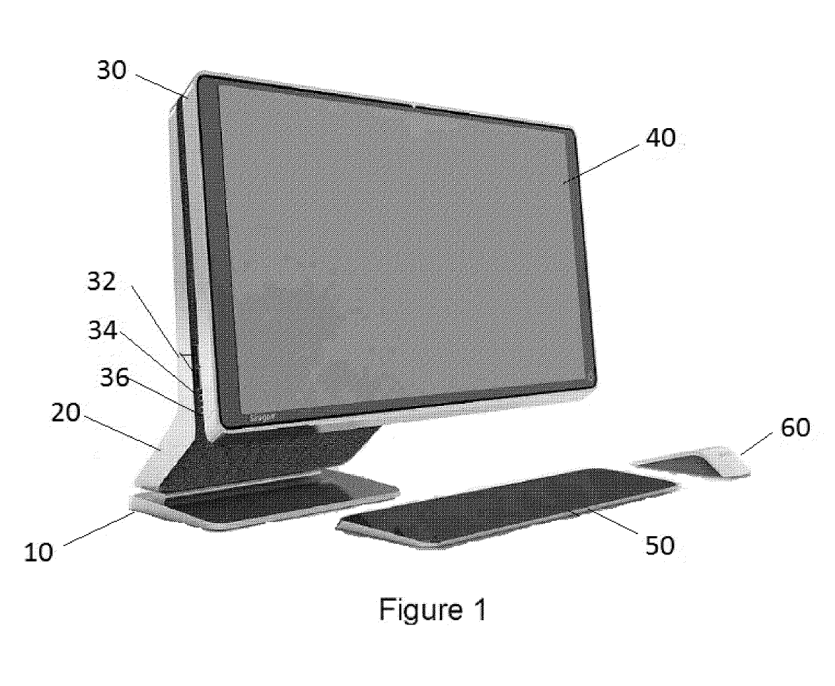

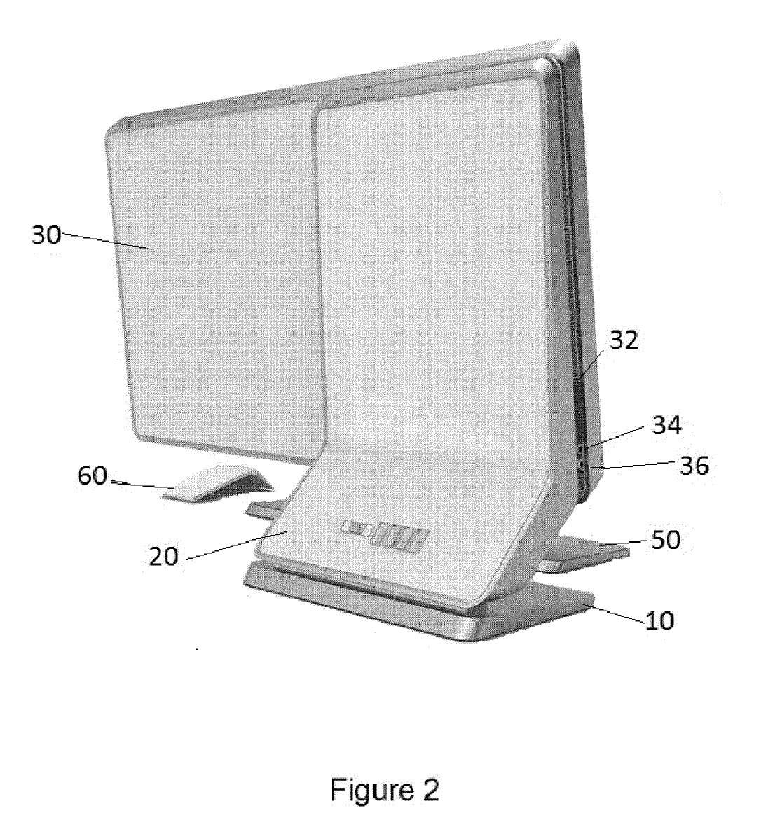

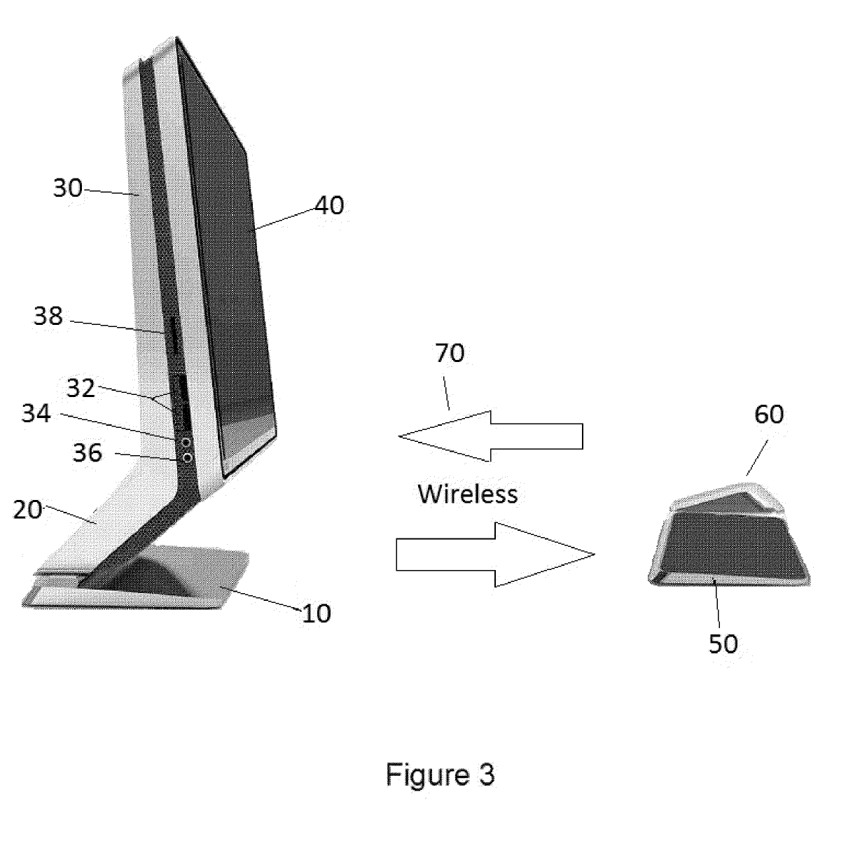

The current invention is an ergonomic all in one computer with the key components of a base 10, a leg 20, a cabinet 30 with a LCD monitor 40 on one side, a wireless mouse 60 and a wireless keyboard 50 as shown in FIGS. 1-3.

The computer has a flat base 10 which presents a low profile which is rectangular in shape in the preferred embodiment. A leg 2 is attached to the base and to the back of the cabinet 40. The leg extends out at 45 degree angle from the back of the base and angles back when attached to the cabinet 30 to position the cabinet 30 at a slight angle away from where a user would view the screen 40. The leg 20 is attached to the left side only of the cabinet 30. This produces a cantilevered effect that seems to suspend the screen 40 weightlessly over the work adding to the artistic look and feel of the computer.

On the side of the cabinet 30 are the ports such as a memory card port 38, one or more USB ports 32, a microphone port 34 and headset port 36. In the preferred embodiment these ports are on the lefts side of the cabinet 30 on the same side as the leg 20.

The screen 40 is on the front side of the cabinet 30. It the preferred embodiment it is a flat screen such as an LCD with a large screen size to provide the user with the optimal viewing of their work or gaming.

The mouse 60 and keyboard 50 in the preferred embodiment has the same cantilever design form. They are connected to the computer through the use of a wireless system 70 in the preferred embodiment. This allows ease of use by the user. Each will have through own power source which in the preferred embodiment will be a series of batteries.

The cabinet 30 will house the microprocessor, the wireless sender and receiver and all the processing components and wiring. It the preferred embodiment it will be the latest state of the art. The heat will be vented through the mesh layer in the cabinet 30 which is positioned midway between the front and back of the cabinet 30. It can run up the sides and top of the cabinet 30 as well as the bottom. This will help prevent the computer from overheating.

The computer can also have a standard disk drive if desired but this is not in the preferred embodiment.

All description giving is for clarification purposes only, and not attended to limit the invention features and embodiment measurements. Further aspects of the invention will become clear from consideration of the drawings and the ensuing description of the glove preferred embodiments. A person skilled in the art will realize that other embodiments of the glove can vary and the details of the invention can be modified in a number of respects, all without departing from the inventive concept. Thus, the following drawings and descriptions are to be regarded as illustrative in nature and not restrictive.

With respect to the above description, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur by those skilled in the art, it is not desired to limit the invention to the exact construction and operation shown and described, and accordingly, all suitable modifications and equivalents may be resorted to, falling within the scope of the invention.

I claim:

1. A computer comprising:
a base attached to a leg which is attached to a cabinet with a LCD monitor on one side.

2. A device according to claim 1 further comprising having a wireless mouse and a keyboard.

3. A device according to claim 2 further comprising having the wireless mouse and the keyboard have a cantilever design.

3. A device according to claim 1 further comprising having the base have a flat rectangular shape.

4. A device according to claim 1 further comprising having the leg extend out at 45 degree angle from the back of the base.

5. A device according to claim 1 further comprising having the leg angle back when attached to the cabinet to position the cabinet at a slight angle away from where a user would view the screen.

6. A device according to claim 1 further comprising having the leg attached to the left side only of the cabinet.

7. A device according to claim 6 further comprising having the leg produces a cantilevered effect when attached to the cabinet.

8. A device according to claim 1 further comprising having ports on the side of the cabinet.

9. A device according to claim 1 further comprising having the screen located on the front side of the cabinet.

10. A device according to claim 9 further comprising having screen be an LCD screen.

11. A device according to claim 1 further comprising having a mesh layer.

12. A device according to claim 11 further comprising having the mesh layer run up the sides and top of the cabinet.

13. A computer comprising:
a base attached to a leg which is attached to a cabinet with a LCD monitor on the front side, having a wireless mouse and a keyboard, having the base have a flat rectangular shape with the leg extending out at 45 degree angle from the back of the base and angle back when attached to the cabinet to position the cabinet at a slight angle away from where a user would view the screen and connected only to the left side only of the cabinet producing a cantilevered effect when attached to the cabinet.

14. A device according to claim 13 further comprising having the wireless mouse and the keyboard have a cantilever design.

15. A device according to claim 13 further comprising having ports on the side of the cabinet.

16. A device according to claim 13 further comprising having the screen be an LCD screen.

17. A device according to claim 13 further comprising having a mesh layer.

18. A device according to claim 13 further comprising having the mesh layer run up the sides and top of the cabinet.
